(19) United States
(12) Patent Application Publication
(10) Pub. No.: US 2025/0247175 A1
(43) Pub. Date: Jul. 31, 2025

(54) POLAR CODED DATA RATE MATCHING AND HARQ TRANSMISSION

(71) Applicant: Samsung Electronics Co., Ltd., Suwon-si (KR)

(72) Inventors: Heping Wan, Plano, TX (US); Joonyoung Cho, Portland, OR (US)

(21) Appl. No.: 19/011,457

(22) Filed: Jan. 6, 2025

Related U.S. Application Data
(60) Provisional application No. 63/626,127, filed on Jan. 29, 2024.

(51) Int. Cl. H04L 1/1867; H04L 5/00

(52) U.S. Cl. CPC H04L 1/1896; H04L 5/0046

(57) ABSTRACT

An electronic apparatus includes a processor configured to construct a set of equivalent puncturing pattern (EPP) sequences for polar-coded HARQ transmissions. The set of EPP sequences include an initial sequence and a set of permuted sequences. Each sequence includes elements representing a sub-block puncturing pattern. The processor is also configured to select an EPP sequence from the set of EPP sequences. The electronic apparatus also includes a transceiver operatively coupled to the processor. The transceiver is configured to transmit a polar-coded HARQ transmission. The polar-coded HARQ transmission is punctured according to the selected EPP sequence.

### CROSS-REFERENCE TO RELATED APPLICATION(S) AND CLAIM OF PRIORITY

This application claims priority under 35 U.S.C. § 119(e) to U.S. Provisional Patent Application No. 63/626,127 filed on Jan. 29, 2024. The above-identified provisional patent application is hereby incorporated by reference in its entirety.

### TECHNICAL FIELD

This disclosure relates generally to wireless networks. More specifically, this disclosure relates to polar coded data rate matching and hybrid automatic repeat request (HARQ) transmission.

### BACKGROUND

The demand of wireless data traffic is rapidly increasing due to the growing popularity among consumers and businesses of smart phones and other mobile data devices, such as tablets, “note pad” computers, net books, eBook readers, and machine type of devices. In order to meet the high growth in mobile data traffic and support new applications and deployments, improvements in radio interface efficiency and coverage is of paramount importance.

To meet the demand for wireless data traffic having increased since deployment of 4G communication systems, and to enable various vertical applications, 5G communication systems have been developed and are currently being deployed. The enablers for the 5G/NR mobile communications include massive antenna technologies, from legacy cellular frequency bands up to high frequencies, to provide beamforming gain and support increased capacity, new waveform (e.g., a new radio access technology [RAT]) to flexibly accommodate various services/applications with different requirements, new multiple access schemes to support massive connections, and so on.

### SUMMARY

This disclosure provides apparatuses and methods for polar coded data rate matching and HARQ transmission.

In one embodiment, an electronic apparatus is provided. The electronic apparatus includes a processor. The processor is configured to construct a set of equivalent puncturing pattern (EPP) sequences for polar-coded hybrid automatic repeat request (HARQ) transmissions. The set of EPP sequences include an initial sequence and a set of permuted sequences. Each sequence includes elements representing a sub-block puncturing pattern. The processor is also configured to select an EPP sequence from the set of EPP sequences. The electronic apparatus also includes a transceiver operatively coupled to the processor. The transceiver is configured to transmit a polar-coded HARQ transmission. The polar-coded HARQ transmission is punctured according to the selected EPP sequence.

In another embodiment, a method of operating an electronic apparatus is provided. The method includes constructing a set of EPP sequences for polar-coded HARQ transmissions. The set of EPP sequences include an initial sequence and a set of permuted sequences. Each sequence includes elements representing a sub-block puncturing pattern. The method also includes selecting an EPP sequence from the set of EPP sequences, and transmitting a polar-coded HARQ transmission. The polar-coded HARQ transmission is punctured according to the selected EPP sequence.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

The following documents and/or standards descriptions are hereby incorporated by reference into the present disclosure as if fully set forth herein.
[1] E. Arikan, “Channel Polarization: A Method for Constructing Capacity-Achieving Codes for Symmetric Binary-Input Memoryless Channels,” in IEEE Transactions on Information Theory, vol. 55, no. 7, pp. 3051-3073, July 2009.
[2] Chen, Kai, et al. “Equivalent puncture sets for polar coded re-transmissions.” U.S. Pat. No. 11,411,678. 9 Aug. 2022.
[3] Y. Zhang, K. Qin, C. Jiao and Z. Zhang, “A Hybrid ARQ Scheme Based on Equivalent Puncturing Patterns of Polar Codes,” 2018 IEEE 88th Vehicular Technology Conference (VTC-Fall), Chicago, IL, USA, 2018, pp. 1-5.
[4] L. Chandesris, V. Savin and D. Declercq, “On puncturing strategies for polar codes,” 2017 IEEE International Conference on Communications Workshops (ICC Workshops), Paris, France, 2017, pp. 766-771.

### BRIEF DESCRIPTION OF THE DRAWINGS

For a more complete understanding of this disclosure and its advantages, reference is now made to the following description, taken in conjunction with the accompanying drawings, in which:

FIG. 1 illustrates an example wireless network according to embodiments of the present disclosure;

FIGS. 2A and 2B illustrate example wireless transmit and receive paths according to embodiments of the present disclosure;

FIG. 3A illustrates an example UE according to embodiments of the present disclosure;

FIG. 3B illustrates an example gNB according to embodiments of the present disclosure;

FIG. 4 illustrates an example diagram of polar-coded retransmissions according to embodiments of the present disclosure;

FIG. 5 illustrates a flowchart for an example method to construct puncturing patterns and perform HARQ transmissions according to embodiments of the present disclosure;

FIG. 6 illustrates a flowchart for an example method to generate a sequence according to a sub-block puncturing pattern according to embodiments of the present disclosure;

FIG. 7 illustrates a flowchart for an example method to generate permuted sequences according to embodiments of the present disclosure;

FIG. 8 illustrates a flowchart for an example method to generate a sub-block puncturing pattern according to a sequence according to embodiments of the present disclosure;

FIG. 9 illustrates a flow chart for an example method to select sub-block puncturing patterns for retransmissions according to embodiments of the present disclosure;

FIG. 10 illustrates a flowchart for another example method to construct puncturing patterns and perform HARQ transmissions according to embodiments of the present disclosure; and

FIG. 11 illustrates an example method for polar coded data rate matching and HARQ transmission according to embodiments of the present disclosure.

### DETAILED DESCRIPTION

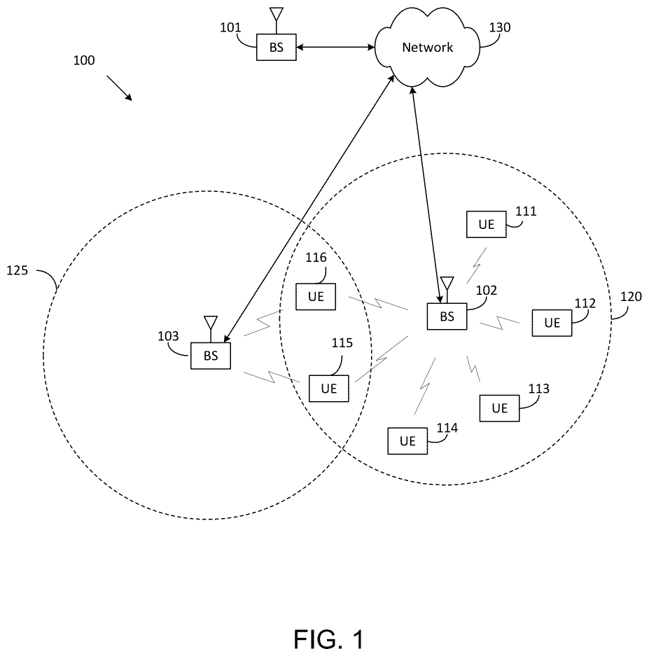

FIGS. 1 through 11, discussed below, and the various embodiments used to describe the principles of this disclosure in this patent document are by way of illustration only and should not be construed in any way to limit the scope of the disclosure. Those skilled in the art will understand that the principles of this disclosure may be implemented in any suitably arranged wireless communication system.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHz, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (CoMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3B below describe various embodiments implemented in wireless communications systems and with the use of orthogonal frequency division multiplexing (OFDM) or orthogonal frequency division multiple access (OFDMA) communication techniques. The descriptions of FIGS. 1-3B are not meant to imply physical or architectural limitations to the manner in which different embodiments may be implemented. Different embodiments of the present disclosure may be implemented in any suitably arranged communications system.

FIG. 1 illustrates an example wireless network 100 according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, longterm evolution (LTE), longterm evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the LUE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof, for polar coded data rate matching and HARQ transmission. In certain embodiments, one or more of the gNBs 101-103 includes circuitry, programing, or a combination thereof, to support polar coded data rate matching and HARQ transmission in a wireless communication system.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

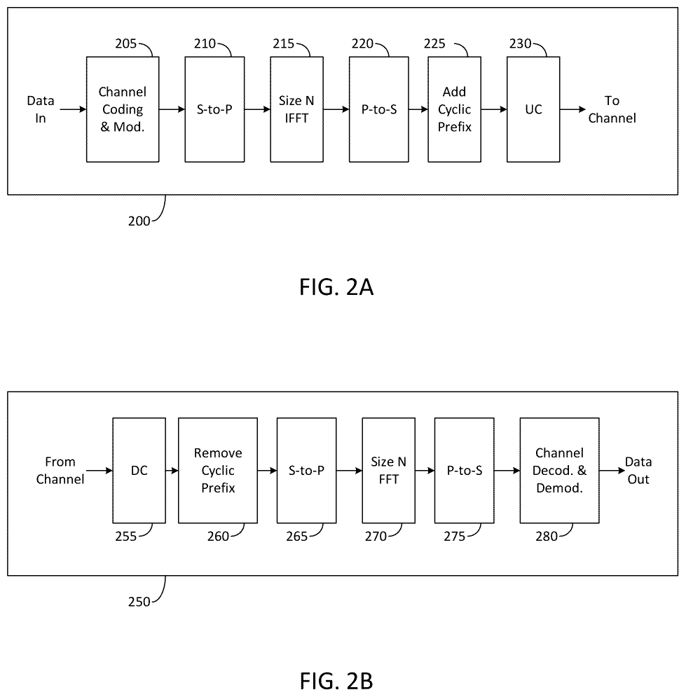

FIGS. 2A and 2B illustrate example wireless transmit and receive paths according to embodiments of the present disclosure. In the following description, a transmit path 200 may be described as being implemented in a gNB (such as gNB 102), while a receive path 250 may be described as being implemented in a UE (such as UE 116). However, it will be understood that the receive path 250 can be implemented in a gNB and that the transmit path 200 can be implemented in a UE. In some embodiments, the transmit path 200 and/or the receive path 250 is configured to implement and/or support polar coded data rate matching and HARQ transmission as described in embodiments of the present disclosure.

The transmit path 200 includes a channel coding and modulation block 205, a serial-to-parallel (S-to-P) block 210, a size N Inverse Fast Fourier Transform (IFFT) block 215, a parallel-to-serial (P-to-S) block 220, an add cyclic prefix block 225, and an up-converter (UC) 230. The receive path 250 includes a down-converter (DC) 255, a remove cyclic prefix block 260, a serial-to-parallel (S-to-P) block 265, a size N Fast Fourier Transform (FFT) block 270, a parallel-to-serial (P-to-S) block 275, and a channel decoding and demodulation block 280.

In the transmit path 200, the channel coding and modulation block 205 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 210 converts (such as de-multiplexes) the serial modulated symbols to parallel data in order to generate N parallel symbol streams, where N is the IFFT/FFT size used in the gNB 102 and the UE 116. The size N IFFT block 215 performs an IFFT operation on the N parallel symbol streams to generate time-domain output signals. The parallel-to-serial block 220 converts (such as multiplexes) the parallel time-domain output symbols from the size N IFFT block 215 in order to generate a serial time-domain signal. The add cyclic prefix block 225 inserts a cyclic prefix to the time-domain signal. The up-converter 230 modulates (such as up-converts) the output of the add cyclic prefix block 225 to an RF frequency for transmission via a wireless channel. The signal may also be filtered at baseband before conversion to the RF frequency.

A transmitted RF signal from the gNB 102 arrives at the UE 116 after passing through the wireless channel, and reverse operations to those at the gNB 102 are performed at the UE 116. The down-converter 255 down-converts the received signal to a baseband frequency, and the remove cyclic prefix block 260 removes the cyclic prefix to generate a serial time-domain baseband signal. The serial-to-parallel block 265 converts the time-domain baseband signal to parallel time domain signals. The size N FFT block 270 performs an FFT algorithm to generate N parallel frequency-domain signals. The parallel-to-serial block 275 converts the parallel frequency-domain signals to a sequence of modulated data symbols. The channel decoding and demodulation block 280 demodulates and decodes the modulated symbols to recover the original input data stream.

Each of the gNBs 101-103 may implement a transmit path 200 that is analogous to transmitting in the downlink to UEs 111-116 and may implement a receive path 250 that is analogous to receiving in the uplink from UEs 111-116. Similarly, each of UEs 111-116 may implement a transmit path 200 for transmitting in the uplink to gNBs 101-103 and may implement a receive path 250 for receiving in the downlink from gNBs 101-103.

Each of the components in FIGS. 2A and 2B can be implemented using only hardware or using a combination of hardware and software/firmware. As a particular example, at least some of the components in FIGS. 2A and 2B may be implemented in software, while other components may be implemented by configurable hardware or a mixture of software and configurable hardware. For instance, the FFT block 270 and the IFFT block 215 may be implemented as configurable software algorithms, where the value of size N may be modified according to the implementation.

Furthermore, although described as using FFT and IFFT, this is by way of illustration only and should not be construed to limit the scope of this disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 2A and 2B illustrate examples of wireless transmit and receive paths, various changes may be made to FIGS. 2A and 2B. For example, various components in FIGS. 2A and 2B can be combined, further subdivided, or omitted and additional components can be added according to particular needs. Also, FIGS. 2A and 2B are meant to illustrate examples of the types of transmit and receive paths that can be used in a wireless network. Any other suitable architectures can be used to support wireless communications in a wireless network.

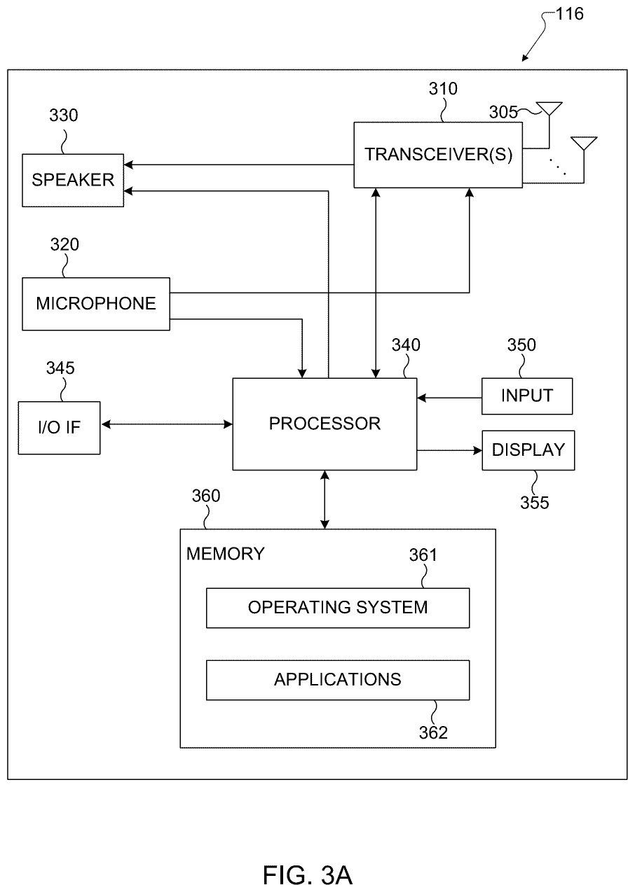

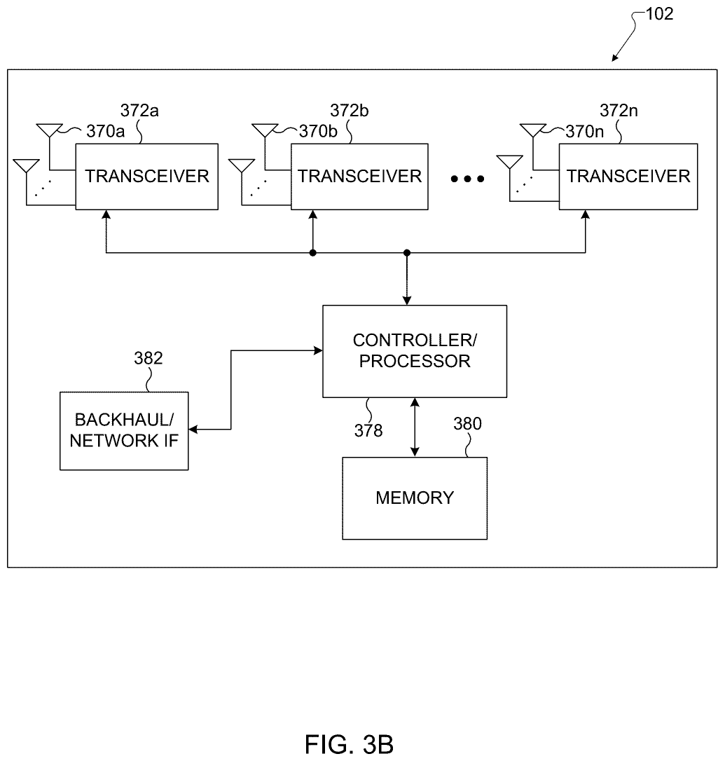

FIG. 3A illustrates an example UE 116 according to embodiments of the present disclosure. The embodiment of the UE 116 illustrated in FIG. 3A is for illustration only, and the UEs 111-115 of FIG. 1 could have the same or similar configuration. However, UEs come in a wide variety of configurations, and FIG. 3A does not limit the scope of this disclosure to any particular implementation of a UE.

As shown in FIG. 3A, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the ULE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360, for example, processes for polar coded data rate matching and HARQ transmission as discussed in greater detail below. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3A illustrates one example of UE 116, various changes may be made to FIG. 3A. For example, various components in FIG. 3A could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3A illustrates the UE 116 configured as a mobile telephone or smartphone, UEs could be configured to operate as other types of mobile or stationary devices.

FIG. 3B illustrates an example gNB 102 according to embodiments of the present disclosure. The embodiment of the gNB 102 illustrated in FIG. 3B is for illustration only, and the gNBs 101 and 103 of FIG. 1 could have the same or similar configuration. However, gNBs come in a wide variety of configurations, and FIG. 3B does not limit the scope of this disclosure to any particular implementation of a gNB.

As shown in FIG. 3B, the gNB 102 includes multiple antennas 370a-370n, multiple transceivers 372a-372n, a controller/processor 378, a memory 380, and a backhaul or network interface 382.

The transceivers 372a-372n receive, from the antennas 370a-370n, incoming RF signals, such as signals transmitted by UEs in the network 100. The transceivers 372a-372n down-convert the incoming RF signals to generate IF or baseband signals. The IF or baseband signals are processed by receive (RX) processing circuitry in the transceivers 372a-372n and/or controller/processor 378, which generates processed baseband signals by filtering, decoding, and/or digitizing the baseband or IF signals. The controller/processor 378 may further process the baseband signals.

Transmit (TX) processing circuitry in the transceivers 372a-372n and/or controller/processor 378 receives analog or digital data (such as voice data, web data, e-mail, or interactive video game data) from the controller/processor 378. The TX processing circuitry encodes, multiplexes, and/or digitizes the outgoing baseband data to generate processed baseband or IF signals. The transceivers 372a-372n up-converts the baseband or IF signals to RF signals that are transmitted via the antennas 370a-370n.

The controller/processor 378 can include one or more processors or other processing devices that control the overall operation of the gNB 102. For example, the controller/processor 378 could control the reception of uplink (UL) channel signals and the transmission of downlink (DL) channel signals by the transceivers 372a-372n in accordance with well-known principles. The controller/processor 378 could support additional functions as well, such as more advanced wireless communication functions. For instance, the controller/processor 378 could support beam forming or directional routing operations in which outgoing/incoming signals from/to multiple antennas 370a-370n are weighted differently to effectively steer the outgoing signals in a desired direction. Any of a wide variety of other functions could be supported in the gNB 102 by the controller/processor 378.

The controller/processor 378 is also capable of executing programs and other processes resident in the memory 380, such as an OS and, for example, processes to support polar coded data rate matching and HARQ transmission as discussed in greater detail below. The controller/processor 378 can move data into or out of the memory 380 as required by an executing process.

The controller/processor 378 is also coupled to the backhaul or network interface 382. The backhaul or network interface 382 allows the gNB 102 to communicate with other devices or systems over a backhaul connection or over a network. The interface 382 could support communications over any suitable wired or wireless connection(s). For example, when the gNB 102 is implemented as part of a cellular communication system (such as one supporting 5G/NR, LTE, or LTE-A), the interface 382 could allow the gNB 102 to communicate with other gNBs over a wired or wireless backhaul connection. When the gNB 102 is implemented as an access point, the interface 382 could allow the gNB 102 to communicate over a wired or wireless local area network or over a wired or wireless connection to a larger network (such as the Internet). The interface 382 includes any suitable structure supporting communications over a wired or wireless connection, such as an Ethernet or transceiver.

The memory 380 is coupled to the controller/processor 378. Part of the memory 380 could include a RAM, and another part of the memory 380 could include a Flash memory or other ROM.

Although FIG. 3B illustrates one example of gNB 102, various changes may be made to FIG. 3B. For example, the gNB 102 could include any number of each component shown in FIG. 3B. Also, various components in FIG. 3B could be combined, further subdivided, or omitted and additional components could be added according to particular needs.

Polar codes [1] were selected as channel codes for the 5G NR control channel, due to polar codes' competitive performance at short block lengths, with the aid of cyclic redundancy check (CRC) and successive cancellation list (SCL) decoding. In practical communication systems, puncturing may be applied to support the rate compatibility of channel codes, where the mother codeword bits whose positions belong to the puncturing pattern are punctured and the remaining bits are transmitted. Rate-compatible channel codes can be combined with retransmissions to improve the reliability of communications, and the combination refers to Hybrid Automatic Repeat Request (HARQ). There have been efforts to design polar-coded HARQ schemes [2, 3] based on equivalent puncturing patterns [4]. The information bits are encoded into a mother polar codeword. In the initial transmission, the mother polar codeword is punctured according to an initial puncturing pattern and transmitted. The transmitter may receive a HARQ negative acknowledgement (NACK) due to the decoding failure at the receiver side, in which case the mother polar codeword is punctured according to a puncturing pattern equivalent to the initial puncturing pattern and retransmitted. A set of puncturing patterns are said to be equivalent if they lead to the same virtual subchannels due to channel polarization [4]. In [2], flipping the binary representations of the indices at which the codeword bits are punctured was applied to determine the equivalent puncturing patterns (EPPs), and in [3], a swapping method was used to find at most N−1 EPPs, where N denotes the length of the mother polar codeword.

It is advantageous for an EPP applied in a current transmission to be different from the puncturing patterns applied in previous transmissions as much as possible, because in this case the codeword bits that are punctured in the previous transmissions can be transmitted in the current transmission. However, existing methods used to generate EPPs for retransmissions are unable to ensure the highest degree of diversity of the generated EPPs. Additionally, existing methods are performed on the fly which increases the complexity of communication systems utilizing the existing methods.

Various embodiments of this disclosure may construct EPPs for retransmissions offline which are independent of code rates and codeword lengths. Because EPPs constructed by various embodiments of the present disclosure have high degree of diversity, more than 0.5 dB gains in terms of BLER are observed over the state of the art.

TABLE 1 defines notation used in the present disclosure.

TABLE 1

| Symbol | Definition |
|---|---|
| K | The number of information bits |
| N | The codeword length of mother polar codes |
| | N = 2ⁿ where n is a natural number. |
| M | The codeword length of punctured polar codes $\frac{N}{2} < M < N$ |
| Q | The number of mother codeword bits to be punctured |
| | P = N − M |
| T | The maximum number of retransmissions |
| t | t ∈ {0,1, . . . , T} where t = 0 corresponds to the initial |
| | transmission. |
| p^{(t)} | The bit puncturing pattern for retransmission t |
| | p(t) = {p₀^{(t)}, p₁^{(t)}, . . . , p_{Q-1}^{(t)}} is a subset of indices |
| | {0,1, . . . , N − 1}. p⁽⁰⁾ is the bit puncturing |
| | pattern for the initial transmission. |
| ┌·┐ | Ceiling function |
| └·┘ | Floor function |

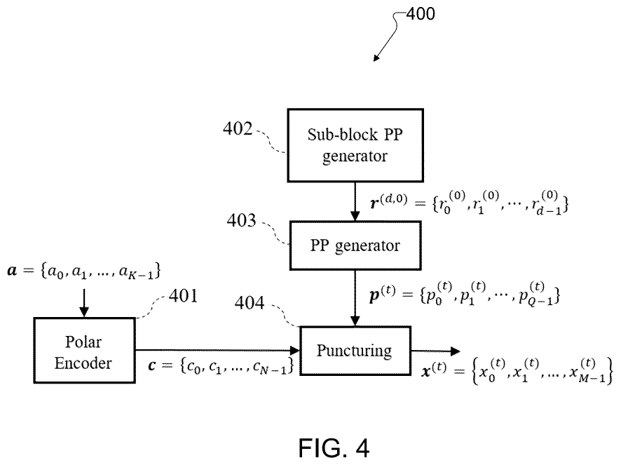

FIG. 4 illustrates an example diagram of polar-coded retransmissions 400 according to embodiments of the present disclosure. The embodiment of polar-coded retransmissions of FIG. 400 is for illustration only. Different embodiments of polar-coded retransmissions could be used without departing from the scope of this disclosure.

In the example of FIG. 4, a={a₀, a₁, . . . , a_{K-1}}, c={c₀, c₁, . . . , c_{N-1}} and x^{(t)}={x₀^{(t)}, x₁^{(t)}, . . . , x_{M-1}^{(t)}} are binary row vectors with length K, N and M, respectively.

At block 401, a polar encoder maps K information bits a into a mother polar codeword c of length N. During polar encoding, CRC bits and dynamic frozen bits/parity check bits may be employed. The construction of the polar codes at block 401 may be according to, but not limited to, density evolution, Bhattacharyya parameter(s) or the Reed-Muller rule. The mother codeword bits can be split into B=2^{m} equally sized sub-blocks, where m is a natural number and 0≤m≤n. The sub-block b,b∈{0, 1, . . . , B−1}, contains bits whose indices are represented as

$$\{ \frac{b \cdot N}{B} , \frac{b \cdot N}{B} + 1 , \frac{b \cdot N}{B} + 2 , … , \frac{b \cdot N}{B} + \frac{N}{B} - 1 \} .$$

At block 402, a sub-block puncturing pattern (PP) for retransmission t is constructed as r^{(d,t)}={r₀^{(t)}, r₁^{(t)}, . . . , r_{d-1}^{(t)}} with

$$d = ⌈ \frac{Q}{N / B} ⌉$$

which is a subset of indices {0, 1, . . . , B−1}. r^{(d,0)} is the sub-block PP for the initial transmission. The bits belonging to the sub-blocks in the sub-block PP r^{(d,t)} may not be included in the retransmission t.

At block 403, the bit puncturing pattern for retransmission t is generated, which comprises the indices of the bits belonging to the sub-block PP r^{(d,t)}{r₀^{(t)}, r₁^{(t)}, . . . , r_{d-1}^{(t)}}, and is presented as

$${p}^{( t )} = \{ \{ \frac{{r}_{0}^{( t )} \cdot N}{B} , \frac{{r}_{0}^{( t )} \cdot N}{B} + 1 , … , \frac{{r}_{0}^{( t )} \cdot N}{B} + \frac{N}{B} - 1 \} , \{ \frac{{r}_{1}^{( t )} \cdot N}{B} , \frac{{r}_{1}^{( t )} \cdot N}{B} + 1 , … , \frac{{r}_{1}^{( t )} \cdot N}{B} + \frac{N}{B} - 1 \} , … , \{ \frac{{r}_{d - 1}^{( t )} \cdot N}{B} , \frac{{r}_{d - 1}^{( t )} \cdot N}{B} + 1 , … , \frac{{r}_{d - 1}^{( t )} \cdot N}{B} + Q - ⌊ \frac{Q}{N / B} ⌋ \cdot \frac{N}{B} - 1 \} \} . \qquad ( 1 )$$

All of the bits in the sub-blocks {r₀^{(t)}, r₁^{(t)}, . . . , r_{d-2}^{(t)}} are punctured and

$$( Q - ⌊ \frac{Q}{N / B} ⌋ \cdot \frac{N}{B} )$$

bits in the sub-block r_{d-1}^{(t)} are punctured. The punctured

$$( Q - ⌊ \frac{Q}{N / B} ⌋ \cdot \frac{N}{B} )$$

bits in the sub-block r_{d-1}^{(t)} may be the first

$$( Q - ⌊ \frac{Q}{N / B} ⌋ \cdot \frac{N}{B} )$$

bits in the sub-block r_{d-1}^{(t)} as shown in equation (1) or other

$$( Q - ⌊ \frac{Q}{N / B} ⌋ \cdot \frac{N}{B} )$$

bits in the sub-block r_{d-1}^{(t)}.

At block 404, for retransmission t, a subset of bits {c₀, c₁, . . . , c_{N-1}} whose indices belong to the bit puncturing pattern p^{(t)} are punctured and the remaining bits form the codeword x^{(t)} and are transmitted.

Although FIG. 4 illustrates example diagram of polar-coded retransmissions 400, various changes may be made to FIG. 4. For example, various changes to polar encoder, the puncturing, etc. could be made according to particular needs.

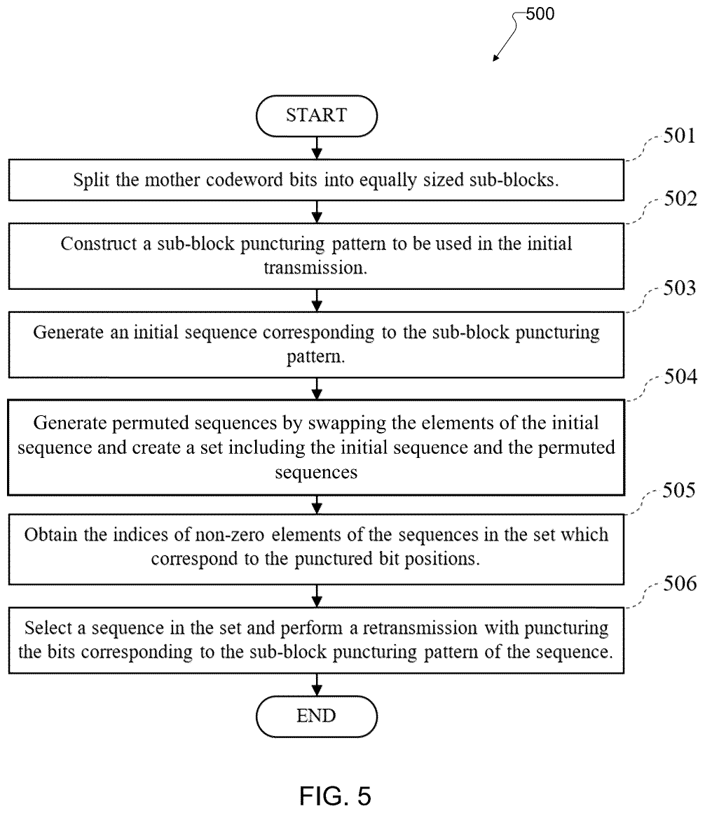

FIG. 5 illustrates a flowchart for an example method to construct puncturing patterns and perform HARQ transmissions 500 according to embodiments of the present disclosure. An embodiment of the method illustrated in FIG. 5 is for illustration only. One or more of the components illustrated in FIG. 5 may be implemented in specialized circuitry configured to perform the noted functions or one or more of the components may be implemented by one or more processors executing instructions to perform the noted functions. Other embodiments of a method to construct puncturing patterns and perform HARQ transmissions could be used without departing from the scope of this disclosure.

In the Example of FIG. 5, method 500 begins at step 501. At step 501, an electronic apparatus (such as BS 102 or UE 116 of FIG. 1) evenly splits a mother codeword of length N into B sub-blocks. Each of the sub-blocks may contain one or multiple bits.

At step 502, the electronic apparatus constructs a sub-block puncturing pattern r^{(d,0)} to be employed in an initial transmission. The sub-block puncturing pattern r^{(d,0)} may be any subset of indices {0, 1, . . . , B−1} with size

$$d = ⌈ \frac{Q}{N / B} ⌉ .$$

The bits corresponding to the sub-block puncturing pattern r^{(d,0)} are punctured in the initial transmission.

At step 503, the electronic apparatus generates an initial sequence corresponding to the sub-block puncturing pattern. The size of the initial sequence is equal to the number of the sub-blocks B. The initial sequence may comprise zero and non-zero elements which correspond to the bits to be transmitted and the bits to be punctured, respectively. In some embodiments, the initial sequence may be generated in accordance with method 600 discussed in greater detail below, where the value ‘0’ is used to tag the sub-blocks of the transmitted bits and +1 or −1 is used to tag the sub-blocks of the punctured bits. In some embodiments, the tagging can be performed with different numbers or in similar ways.

At step 504, the electronic apparatus generates permuted sequences by swapping the elements of the initial sequence. A set is created, and the initial sequence and the permuted sequences are added into the set. In some embodiments, the permuted sequences may be generated in accordance with method 700 discussed in greater detail below.

At step 505, the electronic apparatus obtains the indices of non-zero elements of the sequences in the set which correspond to the punctured bit positions. In some embodiments, the indices may be obtained according to the sequences in accordance with method 800 discussed in greater detail below. The obtained indices of the corresponding sequence in the set represents a sub-block puncturing pattern which becomes an equivalent puncturing pattern of the sub-block puncturing pattern r^{(d,0)}.

At step 506, the electronic apparatus selects a sequence in the set, and a retransmission with bit puncturing corresponding to the puncturing pattern of the sequence is performed. In some embodiments, sub-block puncturing patterns for retransmissions may be selected in accordance with method 900 discussed in greater detail below.

Although FIG. 5 illustrates one example method to construct puncturing patterns and perform HARQ transmissions 500, various changes may be made to FIG. 5. For example, while shown as a series of steps, various steps in FIG. 5 could overlap, occur in parallel, occur in a different order, occur any number of times, be omitted, or replaced by other steps.

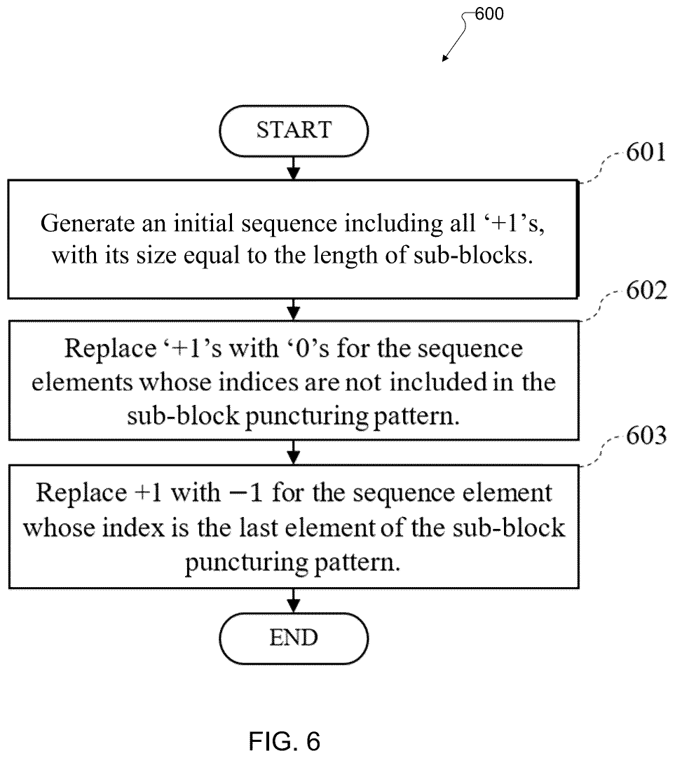

FIG. 6 illustrates a flowchart for an example method to generate a sequence according to a sub-block puncturing pattern 600 according to embodiments of the present disclosure. An embodiment of the method illustrated in FIG. 6 is for illustration only. One or more of the components illustrated in FIG. 6 may be implemented in specialized circuitry configured to perform the noted functions or one or more of the components may be implemented by one or more processors executing instructions to perform the noted functions. Other embodiments of a method to generate a sequence according to a sub-block puncturing pattern could be used without departing from the scope of this disclosure.

As noted above, in some embodiments method 600 may be performed at step 503 of method 500. In some embodiments, method 600 can be used to transform a sub-block puncturing pattern into a sequence of length B, denoted (i₀, y₁, . . . , i_{B-1}), in a one-to-one relationship. The subscript of each element in a sequence is referred to as its index or position.

In the Example of FIG. 6, method 600 begins at step 601. At step 601, an electronic apparatus (such as BS 102 or UE 116 of FIG. 1) generates an initial sequence which comprises all ‘+1’s. The initial sequence has a size equal to the length of sub-blocks. For example, when B=8, the initial sequence is (1,1,1,1,1,1,1,1) where the ‘+” sign is omitted for concise notation.

At step 602, the electronic apparatus replaces ‘+1’s in the initial sequence with ‘0’s for the sequence elements whose indices are not included in the sub-block puncturing pattern. For example, given the sub-block puncturing pattern {0,4,3} which does not include the positions 1, 2, 5, 6 and 7, ‘+1’s of the sequence at positions 1, 2, 5, 6 and 7 are replaced with ‘0’s and hence the initial sequence becomes (1,0,0,1,1,0,0,0).

At step 603, the electronic apparatus replaces the +1 in the initial sequence for the sequence element whose index is the last element of the sub-block puncturing pattern with −1. For example, the last element of the sub-block puncturing pattern {0,4,3} indicates that the replacement is performed at position 3 in the sequence, and therefore ‘+1’ at position 3 is replaced with ‘−1’ and the initial sequence becomes (1,0,0,−1,1,0,0,0).

Although FIG. 6 illustrates one example method to generate a sequence according to a sub-block puncturing pattern 600, various changes may be made to FIG. 6. For example, while shown as a series of steps, various steps in FIG. 6 could overlap, occur in parallel, occur in a different order, occur any number of times, be omitted, or replaced by other steps.

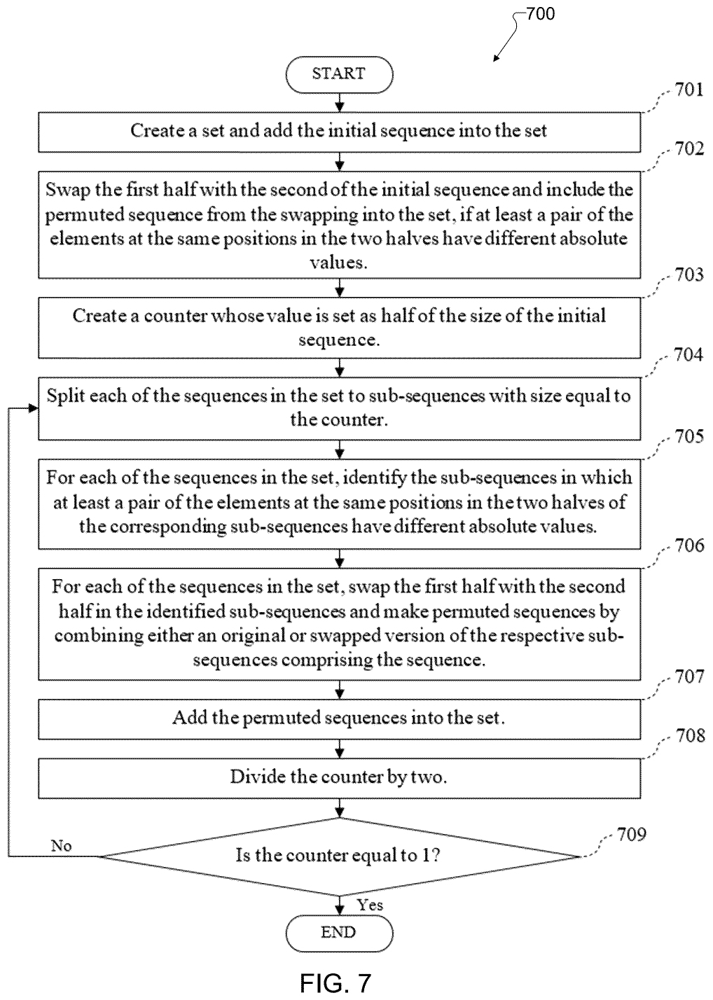

FIG. 7 illustrates a flowchart for an example method to generate permuted sequences 700 according to embodiments of the present disclosure. An embodiment of the method illustrated in FIG. 7 is for illustration only. One or more of the components illustrated in FIG. 7 may be implemented in specialized circuitry configured to perform the noted functions or one or more of the components may be implemented by one or more processors executing instructions to perform the noted functions. Other embodiments of a method to generate permuted sequences could be used without departing from the scope of this disclosure.

As noted above, in some embodiments method 700 may be performed at step 504 of method 500 to generate the permuted sequences according to a sequence.

In the Example of FIG. 7, method 700 begins at step 701. At step 701, an electronic apparatus (such as BS 102 or UE 116 of FIG. 1) creates a set [symbol] and the initial sequence of length B is added into the set.

At step 702, the electronic apparatus swaps the first half of the initial sequence with the second half of the initial sequence, and the permuted sequence is added into [symbol] if at least a pair of the elements at the same positions in the two halves have different absolute values.

At step 703, the electronic apparatus creates a counter k, and counter k's value is set as half of the size of the initial sequence, i.e.,

$$k = \frac{B}{2} .$$

At step 704, the electronic apparatus splits each of the sequences in [symbol] , denoted (i₀, i₁, . . . , i_{B-1}), into B/k sub-sequences of size k.

In the example of FIG. 7, [symbol] _{k,j} denotes the sub-sequence

$$j ∈ \{ 0 , 1 , … , \frac{B}{k} - 1 \}$$

whose elements are represented as

$${\underbrace{( {i}_{j \cdot k} , {i}_{j \cdot k + 1} , … , {i}_{j \cdot k + k / 2 - 1} ,}}_{First half} {\underbrace{{i}_{j \cdot k + k / 2} , … , {i}_{( j + 1 ) \cdot k - 1} )}}_{Second half} .$$

At step 705, if at least a pair of the elements at the same positions in the two halves of [symbol] _{k,j} have different absolute values, the electronic apparatus adds j into a set which is empty initially. That is to say, if (|i_{j·k}|, |i_{j·k+1}|, . . . , |i_{j·k+k/2-1}|)≠(|_{j·k+k/2}|, . . . , |i_{(j+1)·k-1}|), j is added into the set.

At 706, for each of the sequences in [symbol] the electronic apparatus obtains non-empty subsets of the set. For each of the non-empty subsets, the electronic apparatus swaps the first half of [symbol] _{k,j} with the second half of [symbol] _{k,j}, if j belongs to the subset. [symbol] _{k,j} denotes either the original sub-sequence j or the swapped sub-sequence j. The electronic apparatus obtains the permuted sequences by combining the sub-sequences

$$\{ {G}_{k , j} , j ∈ ( 0 , 1 , … , \frac{B}{k} - 1 ) \}$$

either with or without swapping.

At step 707, the electronic apparatus adds the permuted sequences into [symbol] .

At step 708, the electronic apparatus updates the counter by dividing by 2.

At step 709, if k=1 (i.e., the sub-sequence cannot be further divided to generate a smaller sub-sequence), method 700 ends. Otherwise, the electronic apparatus repeats steps 704-708 to generate further sub-sequences.

In the following example regarding method 700, B=8 and the initial sequence is (1,0,−1,0,0,0,0,0). Referring to step 701, the set [symbol] ={(1,0,−1,0,0,0,0,0)}. Referring to step 702, since the first half (1,0,−1,0) and the second half (0,0,0,0) of the initial sequence (1,0,−1,0,0,0,0,0) have different absolute values at corresponding positions 0 and 2, a permuted sequence (0,0,0,0,1,0,−1,0) is obtained by swapping the two halves and added into [symbol] , Therefore,

$$= \{ \begin{matrix}( 1 , 0 , - 1 , 0 , 0 , 0 , 0 , 0 ) , \\ 0 , 0 , 0 , 0 , 1 , 0 , - 1 , 0\end{matrix} \} .$$

Referring to step 703, the counter is set as k=4.

Referring to step 704, the sequence (1,0,−1,0,0,0,0,0) in [symbol] is split into two size-4 sub-sequences as follows:

$${\underbrace{( 1 , 0 , - 1 , 0 )}}_{Sub ‐ sequence j = 0} \qquad {\underbrace{( 0 , 0 , 0 , 0 )}}_{Sub ‐ sequence j = 1}$$

Referring to step 704, the sequence (0,0,0,0,1,0,−1,0) in q is split into two size-4 sub-sequences as follows:

$${\underbrace{( 0 , 0 , 0 , 0 )}}_{Sub ‐ sequence j = 0} \qquad {\underbrace{( 1 , 0 , - 1 , 0 )}}_{Sub ‐ sequence j = 1}$$

Referring to step 705, an empty set [symbol] ₀ for the sequence (1,0,−1,0,0,0,0,0) is created. In the sub-sequence j=0 of the sequence (1,0,−1,0,0,0,0,0), the first half (1,0) and the second half (−1,0) have the same absolute values at corresponding positions 0 and 1, and therefore j=0 is not added into [symbol] ₀. In the sub-sequence j=1 of the sequence (1,0,−1,0,0,0,0,0), the first half (0,0) and the second half (0,0) have the same absolute values at corresponding positions 0 and 1, and therefore j=1 is not added into [symbol] ₀. The set [symbol] ₀ for the sequence (1,0,−1,0,0,0,0,0) is empty. Referring to step 705, an empty set [symbol] ₁ for the sequence (0,0,0,0,1,0,−1,0) is created. In the sub-sequence j=0 of the sequence (0,0,0,0,1,0,−1,0), the first half (0,0) and the second half (0,0) have the same absolute values at corresponding positions 0 and 1, and therefore j=0 is not added into [symbol] ₁. In the sub-sequence j=1 of the sequence (0,0,0,0,1,0,−1,0), the first half (1,0) and the second half (−1,0) have the same absolute values at corresponding positions 0 and 1, and therefore j=1 is not added into [symbol] ₁. The set [symbol] ₁ for the sequence (0,0,0,0,1,0,−1,0) is empty.

Referring to step 706, B₀ and B₁ for the two sequences in [symbol] are both empty. In other words, no sub-sequence is identified, and therefore no permuted sequence is generated from swapping. Referring to step 707,

$$= \{ \begin{matrix}( 1 , 0 , - 1 , 0 , 0 , 0 , 0 , 0 ) , \\ 0 , 0 , 0 , 0 , 1 , 0 , - 1 , 0\end{matrix} \} .$$

Referring to step 708, k=2. Referring to step 709, steps 704-708 are repeated.

Referring to step 704, the sequence (1,0,−1,0,0,0,0,0) in [symbol] is split into four size-2 sub-sequences as follows:

$${{\underbrace{( 1 , 0 )}}_{Sub ‐ sequence}}_{j = 0} \qquad {{\underbrace{( - 1 , 0 )}}_{Sub ‐ sequence}}_{j = 1} \qquad {{\underbrace{( 0 , 0 )}}_{Sub ‐ sequence}}_{j = 2} \qquad {{\underbrace{( 0 , 0 )}}_{Sub ‐ sequence}}_{j = 3}$$

Referring to step 704, the sequence (0,0,0,0,1,0,−1,0) in [symbol] is split into four size-2 sub-sequences as follows.

[symbol]

$${{\underbrace{( 0 , 0 )}}_{Sub ‐ sequence}}_{j = 0} \qquad {{\underbrace{( 0 , 0 )}}_{Sub ‐ sequence}}_{j = 1} \qquad {{\underbrace{( 1 , 0 )}}_{Sub ‐ sequence}}_{j = 2} \qquad {{\underbrace{( - 1 , 0 )}}_{Sub ‐ sequence}}_{j = 3}$$

Referring to step 705, an empty set [symbol] ₀ for the sequence (1,0,−1,0,0,0,0,0) is created. In the sub-sequence j=0 of the sequence (1,0,−1,0,0,0,0,0), the first half 1 and the second half 0 have different absolute values, and therefore j=0 is added into [symbol] ₀. In the sub-sequence j=1 of the sequence (1,0,−1,0,0,0,0,0), the first half −1 and the second half 0 have different absolute values, and therefore j=1 is added into [symbol] ₀. In the sub-sequence j=2 of the sequence (1,0,−1,0,0,0,0,0), the first half 0 and the second half 0 have the same absolute values, and therefore j=2 is not added into [symbol] ₀. In the sub-sequence j=3 of the sequence (1,0,−1,0,0,0,0,0), the first half 0 and the second half 0 have the same absolute values, and therefore j=3 is not added into [symbol] ₀. The set [symbol] ₀ for the sequence (1,0,−1,0,0,0,0,0) becomes {0,1}. Referring to step 705, an empty set [symbol] ₁ for the sequence (0,0,0,0,1,0,−1,0) is created. In the sub-sequence j=0 of the sequence (0,0,0,0,1,0,−1,0), the first half 0 and the second half 0 have the same absolute values, and therefore j=0 is not added into [symbol] ₁. In the sub-sequence j=1 of the sequence (0,0,0,0,1,0,−1,0), the first half 0 and the second half 0 have the same absolute values, and therefore j=1 is not added into [symbol] ₁. In the sub-sequence j=2 of the sequence (0,0,0,0,1,0,−1,0), the first half 1 and the second half 0 have different absolute values, and therefore j=2 is added into 31. In the sub-sequence j=3 of the sequence (0,0,0,0,1,0,−1,0), the first half −1 and the second half 0 have different absolute values, and therefore j=3 is added into [symbol] ₁. The set [symbol] ₁ for the sequence (0,0,0,0,1,0,−1,0) becomes {2,3}.

Referring to 706, the permuted sequences of the initial sequence (1,0,−1,0,0,0,0,0) can be obtained by swapping the elements in the sub-sequences j, where j∈ [symbol] ₀={0,1}. By swapping the two halves in the sub-sequence 0 of the sequence (1,0,−1,0,0,0,0,0), the sub-sequence 0 becomes (0,1). The permuted sequence (0,1,−1,0,0,0,0,0) is obtained by combining the swapped sub-sequence 0 and the original sub-sequences j, where j∈{1,2,3}. By swapping the two halves in the sub-sequence 1 of the sequence (1,0,−1,0,0,0,0,0), the sub-sequence 1 becomes (0,−1). The permuted sequence (1,0,0,−1,0,0,0,0) is obtained by combining the swapped sub-sequence 1 and the original sub-sequences j, where j∈{0,2,3}. The permuted sequence (0,1,0,−1,0,0,0,0) is obtained by combining the swapped sub-sequences j, where j E {0,1}, and the original sub-sequences j, where j∈{2,3}. Referring to step 706, the permuted sequences of the sequence (0,0,0,0,1,0,−1,0) can be obtained by swapping the elements in the sub-sequences j, where j∈ [symbol] ₁={2,3}. By swapping the two halves in the sub-sequence 2 of the sequence (0,0,0,0,1,0,−1,0), the sub-sequence 2 becomes (0,1). The permuted sequence (0,0,0,0,0,1,−1,0) is obtained by combining the swapped sub-sequence 2 and the original sub-sequences j, where j∈{0,1,3}. By swapping the two halves in the sub-sequence 3 of the sequence (0,0,0,0,1,0,−1,0), the sub-sequence 3 becomes (0,−1). The permuted sequence (0,0,0,0,1,0,0,−1) is obtained by combining the swapped sub-sequence 3 and the original sub-sequences j, where j∈{0,1,2}. The permuted sequence (0,0,0,0,0,1,0,−1) is obtained by combining the swapped sub-sequences j, where j∈{2,3}, and the original sub-sequences j, where j∈{0,1}.

Referring to step 707,

$$= \{ \begin{matrix}( 1 , 0 , - 1 , 0 , 0 , 0 , 0 , 0 ) , \\ ( 0 , 0 , 0 , 0 , 1 , 0 , - 1 , 0 ) , \\ ( 0 , 1 , - 1 , 0 , 0 , 0 , 0 , 0 ) , \\ ( 1 , 0 , 0 , - 1 , 0 , 0 , 0 , 0 ) , \\ ( 0 , 1 , 0 , - 1 , 0 , 0 , 0 , 0 ) , \\ ( 0 , 0 , 0 , 0 , 0 , 1 , - 1 , 0 ) , \\ ( 0 , 0 , 0 , 0 , 1 , 0 , 0 , - 1 ) , \\ ( 0 , 0 , 0 , 0 , 0 , 1 , 0 , - 1 )\end{matrix} \} . \qquad ( 2 )$$

Referring to step 708, k becomes 1 and the steps are stopped at step 709.

Although FIG. 7 illustrates one example method to generate permuted sequences 700, various changes may be made to FIG. 7. For example, while shown as a series of steps, various steps in FIG. 7 could overlap, occur in parallel, occur in a different order, occur any number of times, be omitted, or replaced by other steps.

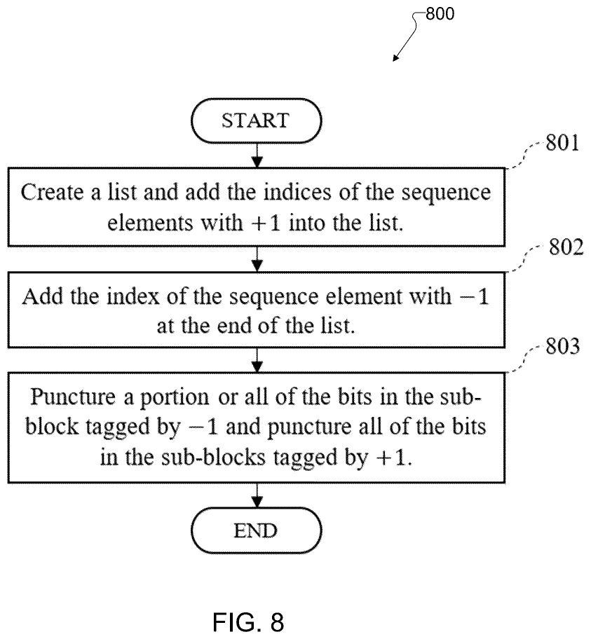

FIG. 8 illustrates a flowchart for an example method to generate a sub-block puncturing pattern according to a sequence 800 according to embodiments of the present disclosure. An embodiment of the method illustrated in FIG. 8 is for illustration only. One or more of the components illustrated in FIG. 8 may be implemented in specialized circuitry configured to perform the noted functions or one or more of the components may be implemented by one or more processors executing instructions to perform the noted functions. Other embodiments of a method to generate a sub-block puncturing pattern according to a sequence could be used without departing from the scope of this disclosure.

As noted above, in some embodiments method 800 may be performed at step 505 of method 500 to generate a sub-block puncturing pattern according to a sequence. In some embodiments, method 800 can transform a sequence of length B into a sub-block puncturing pattern in a one-to-one relationship.

In the Example of FIG. 8, method 800 begins at step 801. At step 801, an electronic apparatus (such as BS 102 or UE 116 of FIG. 1) creates a list [symbol] ′, and the indices of the sequence elements whose value is +1 are added into the list. For example, by adding the indices of the elements with +1 in the sequences shown in Equation (2), [symbol] ′ becomes {{0}, {4}, {1}, {0}, {1}, {5}, {4}, {5}}.

At step 802, the electronic apparatus adds the index of the sequence element whose value is −1 at the end of the list [symbol] ′. For example, by adding the indices of the elements with −1 in the sequences shown in Equation (2),

$${′}^{} = \{ \begin{matrix}\{ 0 , 2 \} , \\ \{ 4 , 6 \} , \\ \{ 1 , 2 \} , \\ \{ 0 , 3 \} , \\ \{ 1 , 3 \} , \\ \{ 5 , 6 \} , \\ \{ 4 , 7 \} , \\ \{ 5 , 7 \}\end{matrix} \} . \qquad ( 3 )$$

At step 803, the electronic apparatus punctures a part or all of the bits in the sub-block tagged by −1, and punctures all of the bits in the sub-blocks tagged by +1. Referring to block 403 of FIG. 4, tag −1 corresponds to the sub-block r_{d-1}^{(t)} in which a part or all of the bits are punctured, and tag 1 corresponds to the sub-blocks {r₀^{(t)}, r₁^{(t)}, . . . , r_{d-2}^{(t)}} in which all of the bits are punctured. The index tagged by −1 may be placed at other positions besides at the end of the list.

Although FIG. 8 illustrates one example method to generate a sub-block puncturing pattern according to a sequence 800, various changes may be made to FIG. 8. For example, while shown as a series of steps, various steps in FIG. 8 could overlap, occur in parallel, occur in a different order, occur any number of times, be omitted, or replaced by other steps.

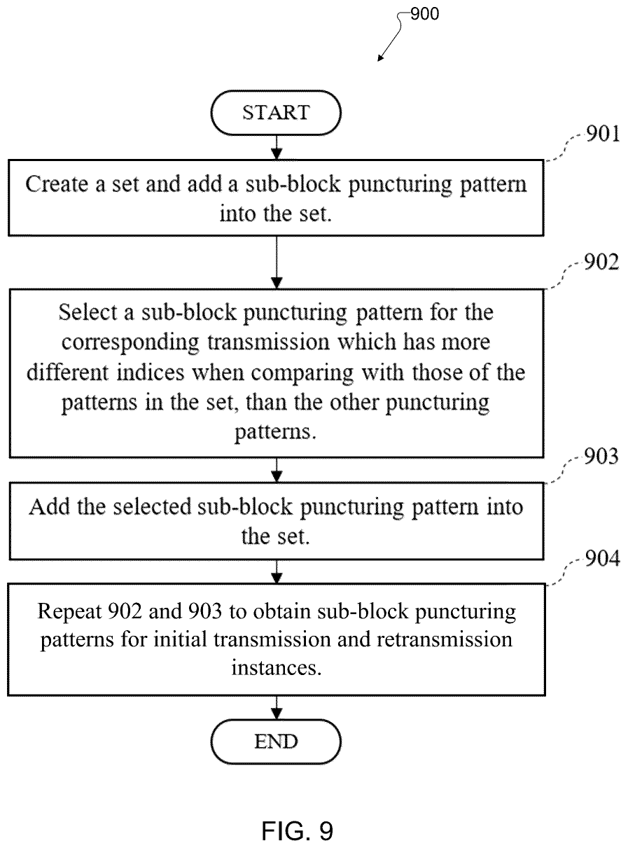

FIG. 9 illustrates a flow chart for an example method to select sub-block puncturing patterns for retransmissions 900 according to embodiments of the present disclosure. An embodiment of the method illustrated in FIG. 9 is for illustration only. One or more of the components illustrated in FIG. 9 may be implemented in specialized circuitry configured to perform the noted functions or one or more of the components may be implemented by one or more processors executing instructions to perform the noted functions. Other embodiments of a method to select sub-block puncturing patterns for retransmissions could be used without departing from the scope of this disclosure.

As noted above, in some embodiments method 900 may be performed at step 506 of method 500 to select the sub-block puncturing patterns for retransmissions. In some embodiments, the steps of method 900 can construct the sub-block puncturing patterns before corresponding retransmissions happen. In some embodiments, the steps of method 900 can be performed to generate a sub-block puncturing pattern when the retransmission t occurs.

In the Example of FIG. 9, method 900 begins at step 901. At step 901, an electronic apparatus (such as BS 102 or UE 116 of FIG. 1) creates a set [symbol] , and a sub-block puncturing pattern denoted r^{(d,0)} is added into [symbol] . r^{(d,0)} may be selected from the set [symbol] ′ in method 500.

In some embodiments, at step 902, the electronic apparatus selects a sub-block puncturing pattern for the corresponding transmission which, when compared with other puncturing patters in the set, has more different indices than the other puncturing patterns in the set. In these embodiments, r^{(d,t)} may denote the sub-block puncturing pattern used for retransmission t. r^{(d,t)} may be selected as an element of [symbol] ′ which maximizes the size of union of the members in [symbol] , and the element that satisfies

$${r}^{( d , t )} = {arg max}_{r ∈ {′}^{}} \vert ( {U}_{{t}^{′} = 0}^{t - 1} {r}^{( d , {t}^{′} )} ) Ur \vert ,$$

where r^{(d,t′)}∈ [symbol] .

In some other embodiments, at step 902, the electronic apparatus selects a sub-block puncturing pattern for the corresponding transmission which is not in the set and, when compared with puncturing patterns in the set, has more different indices than the puncturing patterns in the set. In these embodiments, r^{(d,t)} may denote the sub-block puncturing pattern used for retransmission t. r^{(d,t)} may be selected as an element of [symbol] ′ which maximizes the size of union of the members in [symbol] , and the element that satisfies

$${r}^{( d , t )} = {arg max}_{r ∈ {′}^{}} \vert ( {U}_{{t}^{′} = 0}^{t - 1} {r}^{( d , {t}^{′} )} ) Ur \vert ,$$

where r^{(d,t′)}∈ [symbol] .

In some other embodiments, at step 902, the electronic apparatus selects a sub-block puncturing pattern for the corresponding transmission which has better error-correcting performance than the other puncturing patterns. The method of evaluating the error-correcting performance can be, but is not limited to, density evolution with received signals of corresponding transmissions.

In some other embodiments, at step 902, the electronic apparatus selects a sub-block puncturing pattern for the corresponding transmission which is not in the set and has better error-correcting performance than the other puncturing patterns. The method of evaluating the error-correcting performance can be, but is not limited to, density evolution with received signals of corresponding transmissions.

At step 903, the electronic apparatus adds the selected sub-block puncturing pattern r^{(d,t)} into the set [symbol] .

At step 904, the electronic apparatus repeats steps 902 and 903 to obtain sub-block puncturing patterns for initial transmission and retransmission instances.

In the following example regarding method 900, at most two retransmissions may happen after the initial transmission, and the sub-block puncturing patterns are selected from [symbol] ′ shown in Equation (3). r^{(d,0)} for the initial transmission is selected as {0,2}. Referring to step 901, [symbol] ={{0,2}}. Referring to step 902, {4,6} is selected for the first retransmission. Referring to step 903, [symbol] {{0,2}, {4,6}}. Referring to step 904, steps 902 and 903 are repeated. Referring to step 902, {5,7} is selected for the second retransmission. Referring to step 903, [symbol] ={{0,2}, {4,6}, {5,7}}. Referring to step 904, since the sub-block puncturing patterns for the initial transmission and two retransmissions are obtained, the steps are stopped.

Although FIG. 9 illustrates one example method to select sub-block puncturing patterns for retransmissions 900, various changes may be made to FIG. 9. For example, while shown as a series of steps, various steps in FIG. 9 could overlap, occur in parallel, occur in a different order, occur any number of times, be omitted, or replaced by other steps.

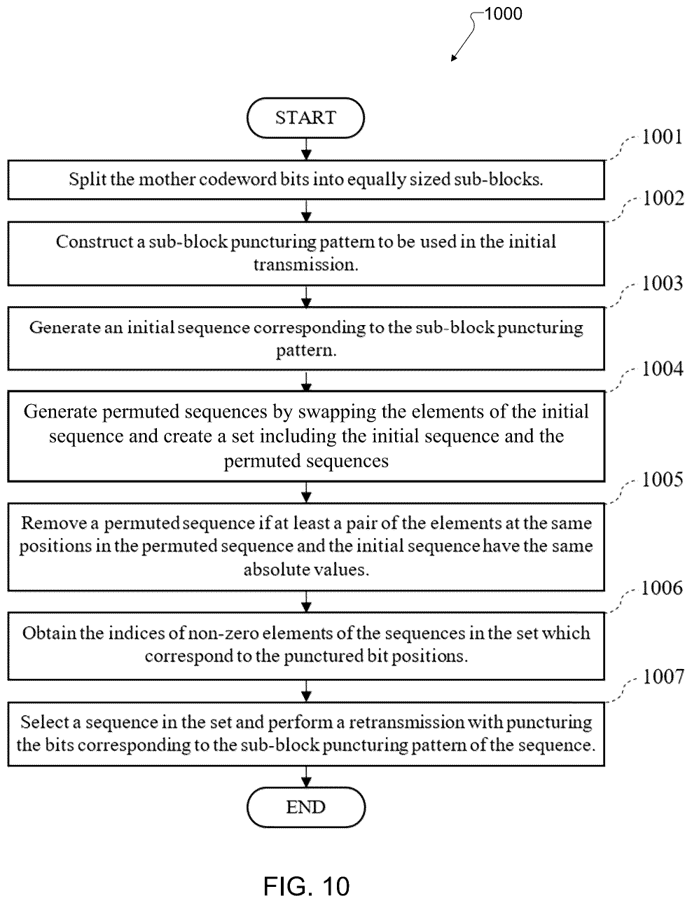

FIG. 10 illustrates a flowchart for another example method to construct puncturing patterns and perform HARQ transmissions 1000 according to embodiments of the present disclosure. An embodiment of the method illustrated in FIG. 10 is for illustration only. One or more of the components illustrated in FIG. 10 may be implemented in specialized circuitry configured to perform the noted functions or one or more of the components may be implemented by one or more processors executing instructions to perform the noted functions. Other embodiments of a method to construct puncturing patterns and perform HARQ transmissions could be used without departing from the scope of this disclosure.

In the Example of FIG. 10, method 1000 begins at step 1001. At step 1001, an electronic apparatus (such as BS 102 or UE 116 of FIG. 1) evenly splits a mother codeword of length N into B sub-blocks. Each of the sub-blocks may contain one or multiple bits.

At step 1002, the electronic apparatus constructs a sub-block puncturing pattern r^{(d,0)} to be employed in the initial transmission. The sub-block puncturing pattern r^{(d,0)} may be any subset of indices (0,1, . . . , B−1) with size

$$d = ⌈ \frac{Q}{N / B} ⌉ .$$

The bits corresponding to the sub-block puncturing pattern r^{(d,0)} are punctured in the initial transmission.

At step 1003, the electronic apparatus generates an initial sequence corresponding to the sub-block puncturing pattern. The size of the initial sequence is equal to the number of the sub-blocks B. The initial sequence comprises zero and non-zero elements which correspond to the bits to be transmitted and the bits to be punctured, respectively. In some embodiments, the initial sequence may be generated in accordance with method 600, where the value ‘0’ is used to tag the sub-blocks of the transmitted bits and +1 or −1 is used to tag the sub-blocks of the punctured bits. In some embodiments, the tagging can be performed with different numbers or in similar ways.

At step 1004, the electronic apparatus generates the permuted sequences by swapping the elements of the initial sequence. A set is created, and the initial sequence and the permuted sequences are added into the set. In some embodiments, the permuted sequences may be generated in accordance with method 700.

At step 1005, the electronic apparatus removes a permuted sequence from the set if at least a pair of the elements at the same positions in the permuted sequence and the initial sequence have the same absolute values.

At step 1006, the electronic apparatus obtains the indices of non-zero elements of the sequences in the set which correspond to the punctured bit positions. In some embodiments, the indices may be obtained according to the sequences in accordance with method 800. The obtained indices of the corresponding sequence in the set represents a sub-block puncturing pattern which becomes an equivalent puncturing pattern of the sub-block puncturing pattern r^{(d,0)}.

At step 1007, the electronic apparatus selects a sequence in the set, and a retransmission with bit puncturing corresponding to the puncturing pattern of the sequence is performed. In some embodiments, sub-block puncturing patterns for retransmissions may be selected in accordance with method 900.

Although FIG. 10 illustrates one example method to construct puncturing patterns and perform HARQ transmissions 1000, various changes may be made to FIG. 10. For example, while shown as a series of steps, various steps in FIG. 10 could overlap, occur in parallel, occur in a different order, occur any number of times, be omitted, or replaced by other steps.

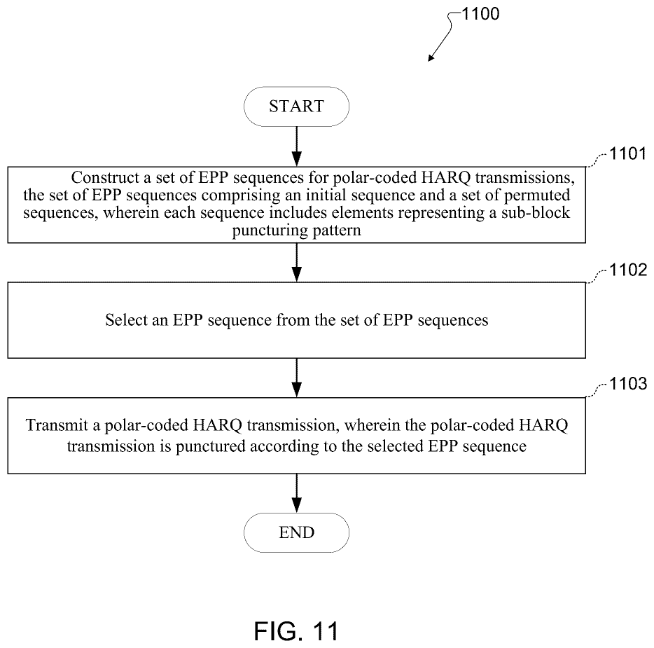

FIG. 11 illustrates an example method for polar coded data rate matching and HARQ transmission 1100 according to embodiments of the present disclosure. An embodiment of the method illustrated in FIG. 11 is for illustration only. One or more of the components illustrated in FIG. 11 may be implemented in specialized circuitry configured to perform the noted functions or one or more of the components may be implemented by one or more processors executing instructions to perform the noted functions. Other embodiments of a method for polar coded data rate matching and HARQ transmission could be used without departing from the scope of this disclosure.

In the Example of FIG. 11, method 1100 begins at step 1101. At step 1101, an electronic apparatus (such as BS 102 or UE 116 of FIG. 1) constructs a set of EPP sequences for polar-coded HARQ transmissions. The set of EPP sequences comprises an initial sequence and a set of permuted sequences. Each sequence includes elements representing a sub-block puncturing pattern.

In some embodiments, to construct the set of EPP sequences, the electronic apparatus: (1) splits a first codeword into a plurality of equally sized sub-blocks; (2) constructs a sub-block puncturing pattern to be used in an initial transmission; (3) generates the initial sequence corresponding to the sub-block puncturing pattern; (4) generates the set of permuted sequences; and (5) obtains indices of non-zero elements of the sequences in the set of EPP sequences which correspond to punctured bit positions.

In some embodiments, to generate the initial sequence, the electronic apparatus: (1) generates a sequence of elements including all ‘+1’s, the size of the sequence equal to a length of the sub-blocks; (2) replaces ‘+1’s with ‘0’s for the elements whose indices are not included in the sub-block puncturing pattern; and (3) replaces +1 with −1 for the element whose index is a last element of the sub-block puncturing pattern.

In some embodiments, to generate the set of permuted sequences, the electronic apparatus swaps elements of the initial sequence.

In some embodiments, to construct the set of EPP sequences, the electronic apparatus iteratively refines the set of permuted sequences based on at least one predefined criterion. In some embodiments, the at least one predefined criterion includes at least a pair of elements at a same position in two halves of a permutated sequence have different absolute values.

At step 1102, the electronic apparatus selects an EPP sequence from the set of EPP sequences.

In some embodiments, the electronic apparatus selects the EPP sequence based on at least one of maximizing a diversity of the sub-block puncturing pattern and maximizing error-correcting performance of the sub-block puncturing pattern.

Finally, at step 1103, the electronic apparatus transmits a polar-coded HARQ transmission. The polar-coded HARQ transmission is punctured according to the selected EPP sequence.

In some embodiments, the selected EPP sequence is the initial sequence, the polar-coded HARQ transmission is an initial HARQ transmission, and the electronic apparatus: (1) receives a HARQ NACK corresponding with the initial HARQ transmission; and (2) in response to receipt of the HARQ NACK, selects an EPP sequence from the set of permuted sequences for puncturing a polar-coded HARQ retransmission.

In some embodiments, the electronic apparatus is a UE, and the UE is configured to transmit the polar-coded HARQ transmission to a BS.

In some embodiments, the electronic apparatus is a BS, and the BS is configured to transmit the polar-coded HARQ transmission to a UE.

Although FIG. 11 illustrates one example method for polar coded data rate matching and HARQ transmission 1100, various changes may be made to FIG. 11. For example, while shown as a series of steps, various steps in FIG. 11 could overlap, occur in parallel, occur in a different order, occur any number of times, be omitted, or replaced by other steps.

Any of the above variation embodiments can be utilized independently or in combination with at least one other variation embodiment. The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claim scope. The scope of patented subject matter is defined by the claims.

What is claimed is:

1. An electronic apparatus comprising:
a processor configured to:
construct a set of equivalent puncturing pattern (EPP) sequences for polar-coded hybrid automatic repeat request (HARQ) transmissions, the set of EPP sequences comprising an initial sequence and a set of permuted sequences, wherein each sequence includes elements representing a sub-block puncturing pattern; and
select an EPP sequence from the set of EPP sequences; and
a transceiver operatively coupled to the processor, the transceiver configured to transmit a polar-coded HARQ transmission, wherein the polar-coded HARQ transmission is punctured according to the selected EPP sequence.

2. The electronic apparatus of claim 1, wherein to construct the set of EPP sequences the processor is further configured to:
split a first codeword into a plurality of equally sized sub-blocks;
construct a sub-block puncturing pattern to be used in an initial transmission;
generate the initial sequence corresponding to the sub-block puncturing pattern;
generate the set of permuted sequences; and
obtain indices of non-zero elements of the sequences in the set of EPP sequences which correspond to punctured bit positions.

3. The electronic apparatus of claim 2, wherein to generate the initial sequence the processor is further configured to:
generate a sequence of elements including all ‘+1’s, the size of the sequence equal to a length of the sub-blocks;
replace ‘+1’s with ‘0’s for the elements whose indices are not included in the sub-block puncturing pattern; and
replace +1 with −1 for the element whose index is a last element of the sub-block puncturing pattern.

4. The electronic apparatus of claim 2, wherein to generate the set of permuted sequences the processor is further configured to swap elements of the initial sequence.

5. The electronic apparatus of claim 2, wherein:
the selected EPP sequence is the initial sequence;
the polar-coded HARQ transmission is an initial HARQ transmission; and
the transceiver is further configured to receive a HARQ negative acknowledgment (NACK) corresponding with the initial HARQ transmission; and
the processor is further configured to in response to receipt of the HARQ NACK select an EPP sequence from the set of permuted sequences for puncturing a polar-coded HARQ retransmission.

6. The electronic apparatus of claim 1, wherein to construct the set of EPP sequences, the processor is further configured to iteratively refine the set of permuted sequences based on at least one predefined criterion.

7. The electronic apparatus of claim 6, wherein the at least one predefined criterion includes at least a pair of elements at a same position in two halves of a permutated sequence have different absolute values.

8. The electronic apparatus of claim 1, wherein the processor is further configured to select the EPP sequence based on at least one of maximizing a diversity of the sub-block puncturing pattern and maximizing error-correcting performance of the sub-block puncturing pattern.

9. The electronic apparatus of claim 1, wherein the electronic apparatus is a user equipment (UE), and the transceiver is configured to transmit the polar-coded HARQ transmission to a base station (BS).

10. The electronic apparatus of claim 1, wherein the electronic apparatus is a base station (BS), and the transceiver is configured to transmit the polar-coded HARQ transmission to a user equipment (UE).

11. A method of operating an electronic apparatus, the method comprising:
constructing a set of equivalent puncturing pattern (EPP) sequences for polar-coded hybrid automatic repeat request (HARQ) transmissions, the set of EPP sequences comprising an initial sequence and a set of permuted sequences, wherein each sequence includes elements representing a sub-block puncturing pattern;
selecting an EPP sequence from the set of EPP sequences; and
transmitting a polar-coded HARQ transmission, wherein the polar-coded HARQ transmission is punctured according to the selected EPP sequence.

12. The method of claim 11, wherein constructing the set of EPP sequences comprises:
splitting a first codeword into a plurality of equally sized sub-blocks;
constructing a sub-block puncturing pattern to be used in an initial transmission;
generating the initial sequence corresponding to the sub-block puncturing pattern;
generating the set of permuted sequences; and
obtaining indices of non-zero elements of the sequences in the set of EPP sequences which correspond to punctured bit positions.

13. The method of claim 12, wherein generating the initial sequence comprises:
generating a sequence of elements including all ‘+1’s, the size of the sequence equal to a length of the sub-blocks;
replacing ‘+1’s with ‘0’s for the elements whose indices are not included in the sub-block puncturing pattern; and
replacing +1 with −1 for the element whose index is a last element of the sub-block puncturing pattern.

14. The method of claim 12, wherein generating the set of permuted sequences comprises to swapping elements of the initial sequence.

15. The method of claim 12, wherein:
the selected EPP sequence is the initial sequence;
the polar-coded HARQ transmission is an initial HARQ transmission; and
the method further comprises:
receiving a HARQ negative acknowledgment (NACK) corresponding with the initial HARQ transmission; and
in response to receipt of the HARQ NACK, selecting an EPP sequence from the set of permuted sequences for puncturing a polar-coded HARQ retransmission.

16. The method of claim 11, wherein constructing the set of EPP sequences comprises iteratively refining the set of permuted sequences based on at least one predefined criterion.

17. The method of claim 16, wherein the at least one predefined criterion includes at least a pair of elements at a same position in two halves of a permutated sequence have different absolute values.

18. The method of claim 11, further comprising selecting the EPP sequence based on at least one of maximizing a diversity of the sub-block puncturing pattern and maximizing error-correcting performance of the sub-block puncturing pattern.

19. The method of claim 11, wherein the electronic apparatus is a user equipment (UE), and the UE is configured to transmit the polar-coded HARQ transmission to a base station (BS).

20. The method of claim 11, wherein the electronic apparatus is a base station (BS), and the BS is configured to transmit the polar-coded HARQ transmission to a user equipment (UE).
